(19) United States
(12) Patent Application Publication
(10) Pub. No.: US 2021/0042621 A1
(43) Pub. Date: Feb. 11, 2021

(54) METHOD FOR OPERATION OF NETWORK MODEL AND RELATED PRODUCT

(71) Applicant: Shenzhen Corerain Technologies Co., Ltd., Shenzhen (CN)

(72) Inventor: Ruizhe Zhao, Shenzhen (CN)

(73) Assignee: Shenzhen Corerain Technologies Co., Ltd., Shenzhen (CN)

(21) Appl. No.: 17/044,502

(22) PCT Filed: Apr. 17, 2018
(86) PCT No.: PCT/CN2018/083436

§ 371 Date: Oct. 1, 2020

(51) Int. Cl. G06N 3/08; G06N 5/04; G06K 9/62

(52) U.S. Cl. CPC G06N 3/08; G06K 9/6232; G06N 5/046

(57) ABSTRACT

Disclosed are a method for operation of a network model and a related product. The method includes: a weight data group sent by a network model compiler is received; p-layer weight data of the network model is updated according to the weight data group to obtain an updated network model; and preset data is extracted, the preset data is input as input data into the updated network model for operation to obtain an output result, and the output result is displayed.

### TECHNICAL FIELD

The present application relates to the technical field of information processing, and particularly to a method for operation of a network model and a related product.

### BACKGROUND

With the continuous development of information technologies and the increasing demand of people, the requirement of people on the timeliness of information becomes higher and higher. Network models such as neural network models have been more and more widely applied along with the development of technologies. The training and operation performed on the network model may be realized for an apparatus such as a computer and a server; however, due to a fact that not all platforms of an existing neural network can complete the training function, a solution for converting a trained network model to the platform application exists. In this way, it cannot be guaranteed that a new hardware structure may be adapted after the conversion, which leads to a reduction in the computational accuracy of the platform, and affects the user experience.

### SUMMARY

Embodiments of the present application provide a method for operation of a network model and a related product, which can realize a simulation operation and a real hardware environment operation of the network model. The simulation operation may test the network model in advance to improve the computational accuracy and the user experience. The real hardware environment operation can directly deploy the network model on a target hardware platform to perform high-performance computation.

In a first aspect, a method for operation of a network model is provided. The method includes: a weight data group sent by a network model compiler is received; n-layer weight data of the network model is updated according to the weight data group to obtain an updated network model; and preset data is extracted, the preset data is input as input data into the updated network model for operation to obtain an output result, and the output result is displayed.

In a second aspect, a platform for operation of a network model is provided. The platform for operation of a network model includes a transceiving unit, an updating unit and a processing unit. The transceiving unit is configured to receive a weight data group sent by a network model compiler. The updating unit is configured to update n-layer weight data of the network model according to the weight data group to obtain an updated network model. The processing unit is configured to extract preset data, input the preset data as input data into the updated network model for operation to obtain an output result, and display the output result.

In a third aspect, a computer-readable storage medium is provided. The computer-readable storage medium stores a computer program for electronic data exchange. The computer program causes a computer to perform the method described in the second aspect.

In a fourth aspect, a computer program product is provided. The computer program product includes a non-transitory computer-readable storage medium storing a computer program, and the computer program is executable to cause a computer to perform the method described in the second aspect.

According to the technical scheme provided by the present application, after the network model is updated, a simulation operation is performed for the network model to obtain an output result, and then the output result is displayed, so that the user can determine whether the network model is suitable for a corresponding hardware structure or not according to this output result, and thus the user experience can be improved. The real hardware environment operation can directly deploy the network model on the target hardware platform to perform high-performance computation.

### BRIEF DESCRIPTION OF DRAWINGS

In order to more clearly explain the technical schemes in embodiments of the present application, the drawings used for describing the embodiments will be briefly introduced below. Obviously, the drawings in the following description are some embodiments of the present application. For those of ordinary skill in the art, other drawings may also be obtained without creative labor according to these drawings.

FIG. 1 is a flowchart of a method for operation of a network model provided by an embodiment of the present application.

FIG. 2 is a structural diagram of a platform for operation of a network model provided by an embodiment of the present application.

### DETAILED DESCRIPTION

The technical schemes in embodiments of the present application will be described clearly and completely below in conjunction with the drawings in the embodiments of the present application. Apparently, the described embodiments are merely part of the embodiments of the present application, rather than all of the embodiments of the present application. All other embodiments obtained by those of ordinary skill in the art based on the embodiments of the present application without requiring creative efforts shall all fall within the scope of protection of the present application.

The terms “first”, “second”, “third”, “fourth, etc., in the description, claims and drawings of the present application are used for distinguishing different objects, rather than describing a particular order. Furthermore, the terms “include” and “have”, as well as any variations thereof, are intended to cover a non-exclusive inclusion. For example, a process, a method, a system, a product, or an apparatus that includes a series of steps or units is not limited to the given steps or units, but optionally further includes steps or units not given, or optionally further includes other steps or units inherent to such process, method, product, or apparatus.

Reference to “embodiment” herein means that a particular feature, structure, or characteristic described in conjunction with the embodiments may be included in at least one embodiment of the present application. The appearance of this word throughout the description does not necessarily all refer to the same embodiment, nor is it an independent or alternative embodiment mutually exclusive from other embodiments. Those skilled in the art understand, clearly and implicitly, that the embodiments described herein may be combined with other embodiments.

Since a mathematical method for simulating an actual neural network of a human comes out, people have been gradually habituated to directly refer to such artificial neural network as a neural network. The neural network has broad and attractive prospects in the fields of system identification, pattern recognition, intelligent control and the like. Especially in intelligent control, people are particularly interested in the self-learning function of the neural network, and this important characteristic of the neural network is regarded as one of keys for solving the problem of the adaptive capability of a controller in automatic control.

The neural network (NN) is a complex network system formed of a large number of simple processing units (referred to as neurons) which are widely connected to each other. The neural network reflects many basic features of the human brain function, and is a highly complex nonlinear power learning system. The neural network has capabilities of large-scale parallelism, distributed storage and processing, self-organization, self-adaptation, and self-learning, and is particularly suitable to deal with the problem of inaccurate and fuzzy information processing that requires simultaneous consideration of many factors and conditions. The development of the neural network is related to neuroscience, mathematical science, cognitive science, computer science, artificial intelligence, information science, control theory, robotics, microelectronics, psychology, optical computation, molecular biology and the like, and is an emerging marginal interdiscipline.

The neural network is based on neurons.

A neuron is a biological model based on a nerve cell of a biological nervous system. When people study the biological nervous system and discuss the mechanism of artificial intelligence, the neuron is represented mathematically, and thus a mathematical model of the neuron is generated.

A large number of neurons of the same form are joined together to form the neural network. The neural network is a highly nonlinear dynamics system. Although the structure and function of each neuron are not complex, the dynamic behavior of the neural network is very complex; therefore, various phenomena in the actual physical world may be expressed by using the neural network.

A neural network model is described based on the mathematical model of the neuron. The artificial neural network is a description of the first order characteristics of a human brain system. Briefly, the artificial neural network is a mathematical model. The neural network model is represented by a network topology, node characteristics and a learning rule. The huge attraction of the neural network to people mainly includes parallel and distributed processing, high robustness and fault-tolerant capability, distributed storage and learning capability, and the capability of fully approximating a complex nonlinear relationship.

Among the research topics of the control field, the problem of controlling an uncertain system has been one of the central themes of the control theory research for a long time, but this problem has never been well solved. The learning capability of the neural network enables the neural network to automatically learn the characteristics of the uncertain system in the process of controlling the system, so as to automatically adapt to the variation of the characteristics of the system along with time, and achieve the optimal control of the system; obviously, this is encouraging intention and method.

There are now dozens of models of the artificial neural network, among which BP neural network, Hopfield network, ART networks and Kohonen network are often used classical neural network models.

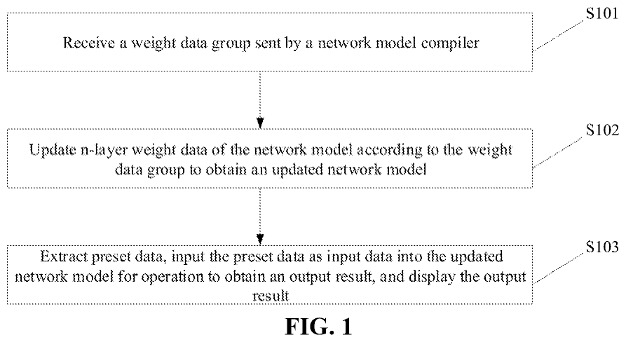

Reference is made to FIG. 1. FIG. 1 is a method for operation of a network model provided by the present application. The method is executed by a neural network chip. The neural network chip may specifically include a dedicated neural network chip, such as an AI chip. Of course, in the practical application, the neural network chip may further include a general-purpose processing chip, such as a CPU or an FPGA. The present application does not limit the specific manifestation of the neural network chip described above, and as shown in FIG. 1, the method described above includes steps described below.

In step S101, a weight data group sent by a network model compiler is received.

There may be multiple receiving manners to receive the weight data group sent by the network model compiler in the above step S101, for example, in an optional technical scheme of the present application, the weight data group may be received in a wireless manner, including but not limited to Bluetooth, WiFi and the like. Of course, in another optional technical scheme of the present application, the weight data group may be received in a wired manner, including but not limited to, a bus manner, a port manner, or a pin manner.

In step S102, n-layer weight data of the network model is updated according to the weight data group to obtain an updated network model.

The implementation method of the step S102 described above may specifically include: weight data corresponding to each layer is extracted in the weight data group, and original weight data of the network model is replaced with the weight data corresponding to the each layer.

In step S103, preset data is extracted, the preset data is input as input data into the updated network model for operation to obtain an output result, and the output result is displayed.

The preset data in the above step may be marked data, and the data may be stored in a software memory of the chip.

The implementation method of the step S103 described above may specifically include: the preset data is extracted, the preset data as the input data is input into the updated network model, and the software memory is called for operation to obtain the output result.

The implementation method of the step S103 described above may specifically further include: all computing nodes of the network model are traversed, a parameter value in the weight data group is imported, a storage space is reserved in a software memory, the all computing nodes are traversed according to a computing sequence, a scheduling strategy of a heterogeneous parallel computation is related to, a computation is performed based on a computing function calling a designated node according to the scheduling strategy, and results are collected to obtain the output result.

According to the technical scheme provided by the present application, after the network model is updated, a simulation operation is performed for the network model to obtain an output result, and then the output result is displayed, so that the user can determine whether the network model is suitable for a corresponding hardware structure or not according to this output result, and thus the user experience can be improved.

A detailed scheme of the above technical scheme is introduced below. For the neural network model, it is divided into two large parts, namely a training and a forward operation. For the training, it is a process of optimizing the neural network model. The specific implementation manner may include described below. A large number of labeled samples (generally 50 or more samples) are sequentially input into an original neural network model (a weight data group at this time has an initial numerical value) to perform iterative operation for multiple times to update an initial weight. Each time of iterative operation includes an n-layer forward operation and an n-layer reverse operation. The weight of the n-layer reverse operation is used for gradient updating of the weight of a corresponding layer, the updating of the weight data group for multiple times may be achieved through computation of multiple samples to complete the training of the neural network model. The trained neural network model receives data to be computed, and the n-layer forward operation is performed on the data to be computed and the trained weight data group to obtain an output result of the forward operation, as such, the output result is analyzed to obtain an operation result of the neural network, and if this neural network model is a neural network model for face recognition, then the operation result thereof is regarded to be matched or mismatched.

For the training of the neural network model, a large amount of computation is needed, since for the n-layer forward operation and the n-layer reverse operation, an amount of computation of any layer relates to a large amount of computation. The neural network model for face recognition is taken as an example, operations at each layer are mostly convolution operations, and input data of convolution has thousands of rows and thousands of columns, then the number of product operations of one convolution operation of such large data can reach 10⁶ times, thus the requirement for a processor is high, a large amount of expenditure needs to be consumed to perform such operation, not to mention that such operation needs to be subjected to multiple iterations and n layers, and each sample needs to be computed once, thereby the computational overhead is further increased. This computational overhead cannot be achieved through an FPGA at present. Excessive computational overhead and power consumption require high hardware configuration. The cost of such hardware configuration is obviously unrealistic for a FPGA device, and therefore for the FPGA, the neural network model is trained with the configured weight data group, but for the FPGA device, a user cannot know that whether the FPGA device adapts to the configured weight data group, and an operation in the chip is performed on one preset data, namely, the operation of the network model is achieved in a manner of calling a soft memory, so that whether the FPGA device is suitable may be determined according to the output result, thereby improving the user experience.

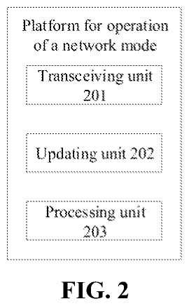

The present application further provides a platform for operation of a network model. Reference is made to FIG. 2, the platform for operation of a network model includes a transceiving unit 201, an updating unit 202 and a processing unit 203.

The transceiving unit 201 is configured to receive a weight data group sent by a network model compiler.

There may be multiple receiving manners to receive the weight data group sent by the network model compiler in the above transceiving unit 201; for example, in an optional technical scheme of the present application, the weight data group may be received in a wireless manner, including but not limited to Bluetooth, WiFi and the like. Of course, in another optional technical scheme of the present application, the weight data group may be received in a wired manner, including but not limited to, a bus manner, a port manner, or a pin manner.

The updating unit 202 is configured to update n-layer weight data of the network model according to the weight data group to obtain an updated network model.

The processing unit 203 is configured to extract preset data, input the preset data as input data into the updated network model for operation to obtain an output result, and display the output result.

According to the technical scheme provided by the present application, after the network model is updated, a simulation operation is performed for the network model to obtain an output result, and then the output result is displayed, so that the user can determine whether the network model is suitable for a corresponding hardware structure or not according to this output result, and thus the user experience can be improved.

Optionally, the updating unit 202 is specifically configured to extract weight data corresponding to each layer in the weight data group, and replace original weight data of the network model with the weight data corresponding to the each layer to obtain the updated network model.

Optionally, the processing unit 203 is specifically configured to input the preset data as the input data into the updated network model and call a software memory for operation to obtain the output result.

The processing unit 203 is specifically configured to traverse all computing nodes of the network model, import a parameter value in the weight data group, reserve a storage space in a software memory, traverse the all computing nodes according to a computing sequence, relate to a scheduling strategy of a heterogeneous parallel computation, compute based on a computing function calling a designated node according to the scheduling strategy, and collect results to obtain the output result.

The present application further provides a computer-readable storage medium. The computer-readable storage medium stores a computer program for electronic data exchange. The computer program causes a computer to perform the method as shown in FIG. 1 and a detailed scheme of this method.

The present application further provides a computer program product. The computer program product includes a non-transitory computer-readable storage medium storing a computer program. The computer program is executable to cause a computer to perform as shown in FIG. 1 and a detailed scheme of this method.

It should be noted that for the foregoing method embodiments, for the sake of simple description, they are all expressed as a series of action combinations, but those skilled in the art should know that the present application is not limited by the described sequence of actions, since certain steps may be performed in other orders or concurrently in accordance with the present application. Secondly, those skilled in the art should also know that the embodiments described in the description are all optional embodiments, and that the actions and modules involved are not necessarily required by the present application.

In the embodiments described above, the description of various embodiments has emphasis on each. For parts that are not described in detail in certain embodiment, reference may be made to related descriptions of other embodiments.

In several embodiments provided in this application, it should be understood that the disclosed device may be implemented in other ways. For example, the device embodiments described above are merely illustrative, for example, the division of said unit is only a logical function division, and there may be additional ways of division in actual implementation, for example multiple units or assemblies may be combined or integrated into another system, or some features may be ignored, or not performed. In addition, the displayed or discussed mutual coupling or direct coupling or communication connection may be an indirect coupling or a communication connection through some interfaces, devices or units, and may be in electrical or other forms.

The units described as separate components may or may not be physically separated, and the components displayed as the unit may or may not be physical units, i.e., they may be located in one place or distributed across multiple network units. Part or all of the units may be selected according to practical requirements to achieve the purpose of the scheme of this embodiment.

In addition, each functional unit in each embodiment of the present application may be integrated into one processing unit, or each unit may exist independently and physically, or two or more units may be integrated into one unit. The integrated unit described above may be realized in the form of hardware or a software program module.

The integrated unit described above, if implemented in the form of a software program module and sold or used as a separate product, may be stored in a computer-readable memory. Based on such understanding, the technical scheme of the present application, either essentially or in terms of contributions to the related art, or all or part of the technical schemes, may be embodied in the form of a software product, and the computer software product is stored in a memory, the memory includes several instructions for enabling a computer apparatus (which may be a personal computer, a server, or a network apparatus, etc.) to perform all or part of the steps of the methods described in the various embodiments of the present application. However, the aforementioned memory includes various media capable of storing program codes, such as a USB flash disk, a read-only memory (ROM), a random access memory (RAM), a mobile hard disk, a magnetic disk or an optical disk.

It should be understood by those of ordinary skill in the art that all or part of the steps in the various methods of the above embodiments may be implemented by a program, which is stored in a computer-readable memory, the memory includes a flash memory disk, a read-only memory (referred to as ROM), a random access memory (referred to as RAM), a magnetic disk or an optical disk.

The embodiments of the present application are described in detail above, and specific examples are used herein to illustrate the principles and implementations of the present application. The description of the above embodiments is merely intended to help understand the method and core ideas of the present application; meanwhile, for a person skilled in the art, according to the idea of the present application, the specific implementation manner and the application scope may be changed, and in summary, the content of the present Description should not be construed as a limitation to the present application.

1. A method for operation of a network model, comprising:
receiving a weight data group sent by a network model compiler;
updating n-layer weight data of the network model according to the weight data group to obtain an updated network model; and
extracting preset data, inputting the preset data as input data into the updated network model for operation to obtain an output result, and displaying the output result.

2. The method of claim 1, wherein updating the n-layer weight data of the network model according to the weight data group to obtain the updated network model specifically comprises:
extracting weight data corresponding to each layer in the weight data group, and replacing original weight data of the network model with the weight data corresponding to the each layer to obtain the updated network model.

3. The method of claim 1, wherein inputting the preset data as the input data into the updated network model for operation to obtain the output result specifically comprises:
inputting the preset data as the input data into the updated network model, and calling a software memory for operation to obtain the output result.

4. The method of claim 1, wherein inputting the preset data as the input data into the updated network model for operation to obtain the output result specifically comprises:
traversing all computing nodes of the network model, importing a parameter value in the weight data group, reserving a storage space in a software memory, traversing the all computing nodes according to a computing sequence, relating to a scheduling strategy of a heterogeneous parallel computation, computing based on a computing function calling a designated node according to the scheduling strategy, and collecting results to obtain the output result.

5. A platform for operation of a network model, comprising:
a processor, which is configured to:
receive a weight data group sent by a network model compiler;
update n-layer weight data of the network model according to the weight data group to obtain an updated network model; and
extract preset data, input the preset data as input data into the updated network model for operation to obtain an output result, and display the output result.

6. The platform for operation of a network model of claim 5, wherein the processor is configured to:
extract weight data corresponding to each layer in the weight data group, and replace original weight data of the network model with the weight data corresponding to the each layer to obtain the updated network model.

7. The platform for operation of a network model of claim 5, wherein the processor is configured to:
input the preset data as the input data into the updated network model and call a software memory for operation to obtain the output result.

8. The platform for operation of a network model of claim 5, wherein the processor is configured to:
traverse all computing nodes of the network model, import a parameter value in the weight data group, reserve a storage space in a software memory, traverse the all computing nodes according to a computing sequence, relate to a scheduling strategy of a heterogeneous parallel computation, compute based on a computing function calling a designated node according to the scheduling strategy, and collect results to obtain the output result.

9. A non-transitory computer-readable storage medium, storing a computer program for electronic data exchange, wherein the computer program causes a computer to perform a method for operation of a network model,
wherein the method comprises:
receiving a weight data group sent by a network model compiler;
updating n-layer weight data of the network model according to the weight data group to obtain an updated network model; and
extracting preset data, inputting the preset data as input data into the updated network model for operation to obtain an output result, and displaying the output result.

10. A computer program product, wherein the computer program product comprises a non-transitory computer-readable storage medium storing a computer program, and the computer program is executable to cause a computer to perform the method of claim 1.
